(19) United States
(12) Patent Application Publication
(10) Pub. No.: US 2009/0307545 A1
(43) Pub. Date: Dec. 10, 2009

(54) TESTABLE MULTIPROCESSOR SYSTEM AND A METHOD FOR TESTING A PROCESSOR SYSTEM

(75) Inventors: Marinus Van Splunter, Bangalore (IN); Evert-Jan Pol, Valkenswaard (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/722,351

(22) PCT Filed: Dec. 9, 2005
(86) PCT No.: PCT/IB2005/054159

§ 371 Date: Aug. 25, 2009

(30) Foreign Application Priority Data
Dec. 20, 2004 (EP) 04106751.3

(51) Int. Cl. G01R 31/3177; G06F 11/25

(52) U.S. Cl. 714/726; 714/E11.155

(57) ABSTRACT

A testable processor system (10,20) comprises a plurality of modules (11, 12, . . . In). Each module (11) comprises a processor unit (110) and a debug controller (111). The debug controllers are coupled to a common test access point controller (TAP-controller 20), and have a test data input (Tin), a test data output (Tout) and at least one test register (112, 113). The test data inputs and outputs of the debug controllers (111, 121, 131, . . . , InI) are arranged in a scan chain having an input for receiving test input data (TDI) from the TAP-controller and an output for providing test output data (TDO) to the TAP-controller. At least one debug controller (111) has a selection facility (115) to select whether data in the scanchain is either shifted through the at least one test register (112) of that debug controller (111) or is immediately forwarded from the test data input (Tin) to the test data output (Tout) of that debug controller. The at least one debug controller has a bypass register (117) which controls the selection facility. The TAP-controller (20) provides a control signal (BYPASS CNTRL) which, when active, selects the bypass register as part of the scan chain.

The more complex systems become the more the need rises to have test facilities that support debugging of the system. To support this need the JTAG (Joint Test Action Group) has developed a standard which provides a generally accepted interface. Therein it is proposed to test a system by coupling a set of registers of the system to be tested in a scanchain. The register may either be registers already arranged for normal operation, or specially created registers for test purposes. Input test data is shifted into the scanchain. After one or more operation cycles output test data is shifted out of the scanchain, and can be analysed. This makes it possible to write and read a large amount of testdata with only a small bandwidth connection.

In a multiprocessor system the required bandwidth would still be large if each module in such a multiprocessor system would have such a scanchain, which would annihilate the advantage. On the other hand if all modules use the same scanchain, the throughput time of the scanchain tends to be high. JTAG provides for a BYPASS mode which makes it possible to select one of the modules in such a system. For this purpose a single bit is reserved for each module, which is read into the scanchain. When this bit is set to a first value for a particular module, the scan registers of that module are normally read and written by the scanchain. By setting this bit to a second value the datastream of the scanchain substantially bypasses those registers. This facilitates debugging a single processor unit of a multiprocessor system, because only a relatively small amount of data has to shifted into and out of the scanchain at each test. However, for large multiprocessor systems e.g. having hundreds of modules the overhead for reading and writing data to the test registers of a particular component is still substantial. For example in a multiprocessor with 200 modules, each time that a 16 bit test address register has to be written or read in addition 200 bypass bits have to be written or read as well, which is an overhead of more than a factor 10.

It is a purpose of the invention to provides a testable multiprocessor system and method for testing a multiprocessor system, which makes it possible to keep the throughput time of the scanchain relatively low without requiring duplication of the scanchain for each module.

A testable multiprocessor system according to the invention is claimed in claim 1.

In the multiprocessor system according to the invention, the selection facility makes it possible to select whether data in the scanchain is either shifted through the at least one test register of that debug controller (test mode) or is immediately forwarded from the test data input to the test data output of that debug controller (bypass mode). If it is not necessary to test a particular module, the testdata can immediately be forwarded from the test data input to the test data output of the corresponding controller. Not only the test registers, but also the bypass register itself is bypassed, so that only the testdata for the module(s) under test need to be scanned in and out the scanchain. On the other hand the module can still be tested by selecting the other option. In that case testing of that module may be accelerated if at least one of the other modules has such a debug controller which is set in bypass mode.

In the testable processor system according to the invention, scan data for the selected module(s) can be read without any overhead. In the embodiment of claim 2, in addition the selection of the modules can take place very efficiently. If the control signal for selecting the bypass register is activated no other data then the data designated for the bypass register needs to be shifted in the scanchain.

In the embodiment of claim 3 each debug controller is capable of causing the other debug controllers to halt their associated processor unit. This makes it possible to independently test a particular module, without interference by the other modules.

A method for testing a multiprocessor system according to the invention is claimed in claim 4.

These and other aspects are described in more detail with reference to the drawings. Therein:

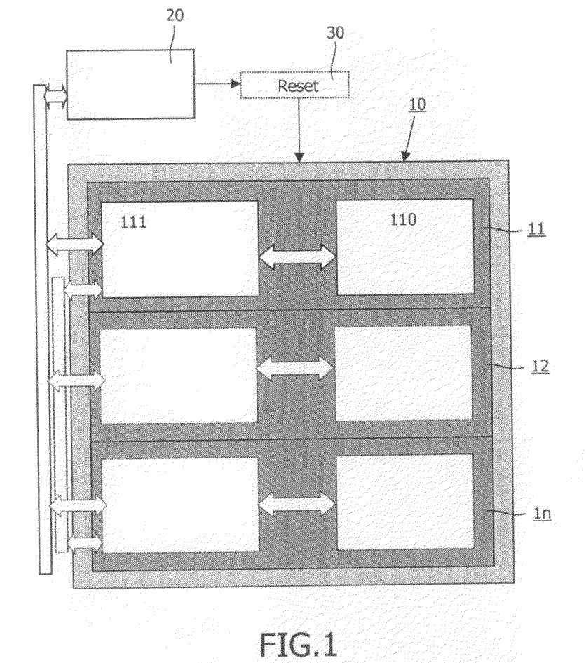

FIG. 1 schematically shows a testable processor system according to the invention,

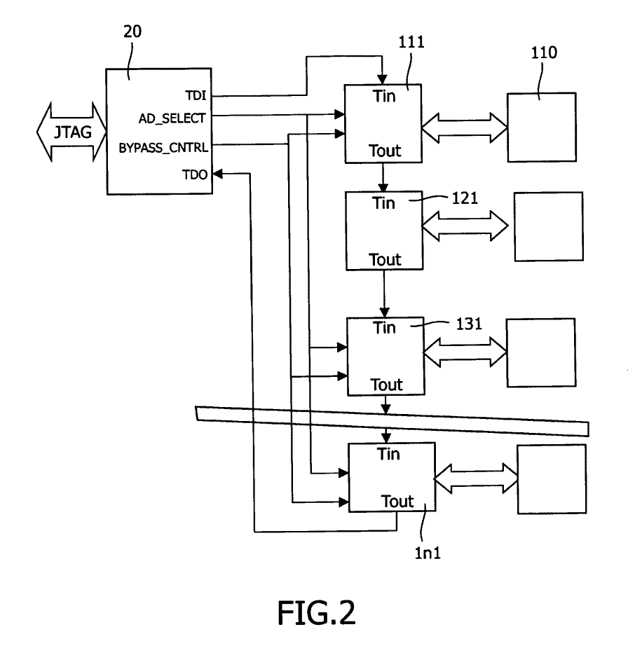

FIG. 2 shows an alternative view of the testable processor system according to the invention,

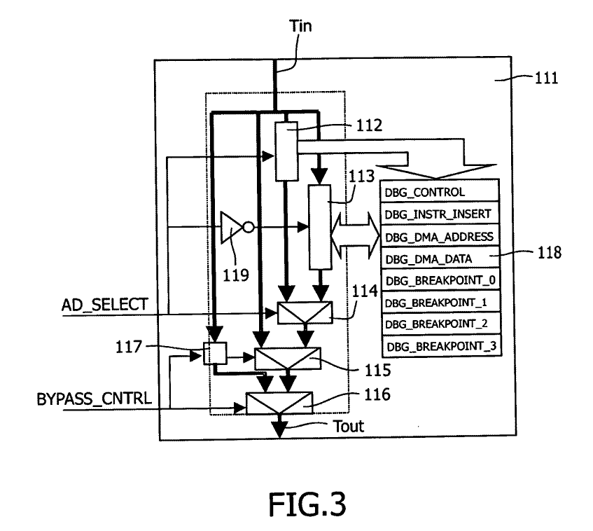

FIG. 3 shows in more detail a debug controller used in the system shown in FIGS. 1 and 2,

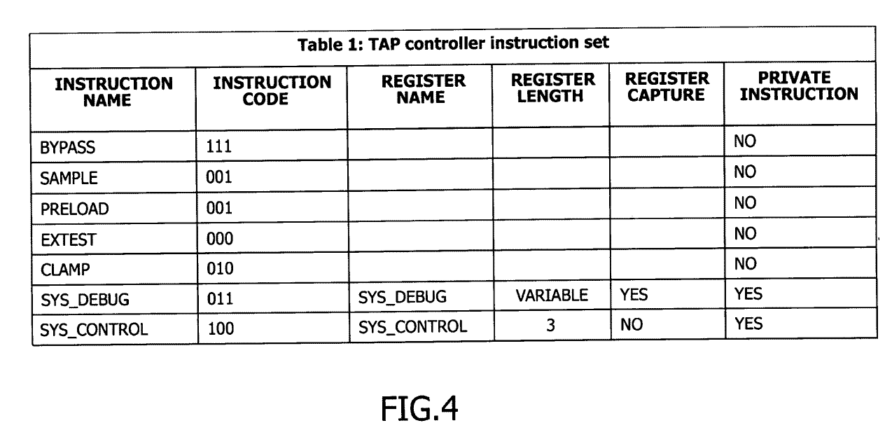

FIG. 4 shows in a first table the instruction set of a TAP-controller used in the system of FIGS. 1 and 2,

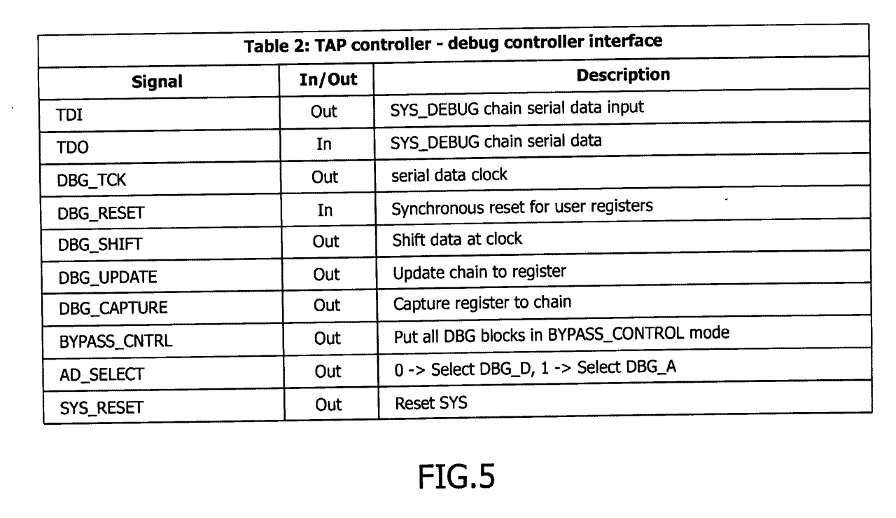

FIG. 5 shows in a second table the signals exchanged between the TAP-controller and the debug controllers,

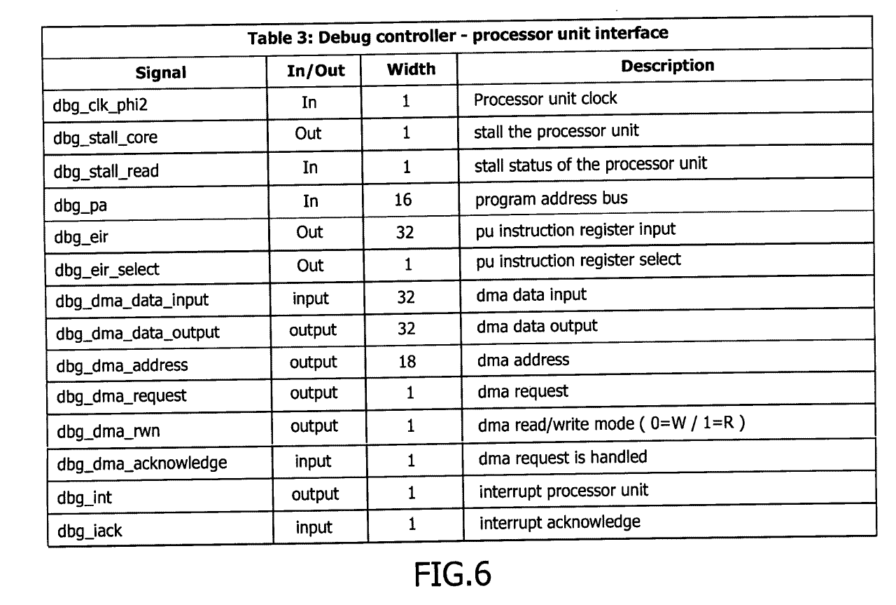

FIG. 6 shows in a third table the signals exchanged between a debug controller and its associated processor unit,

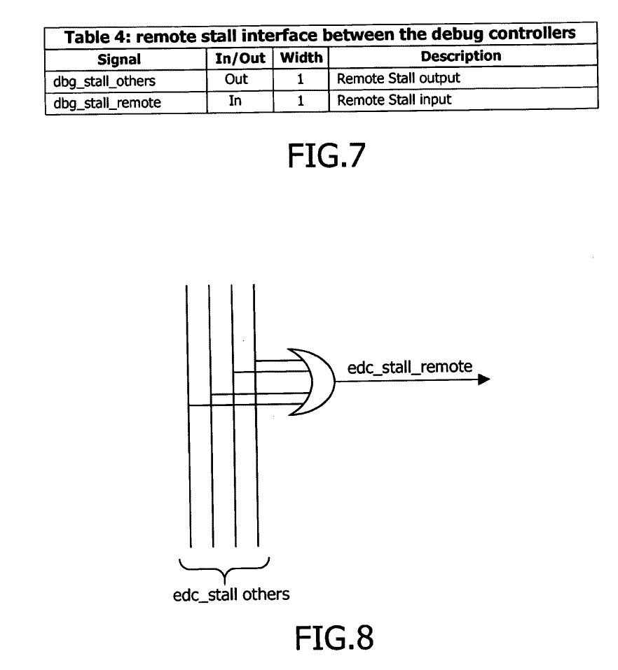

FIG. 7 shows in a fourth table the signals exchanged between debug controllers,

FIG. 8 schematically shows a module for generating a signal for exchange between debug controllers,

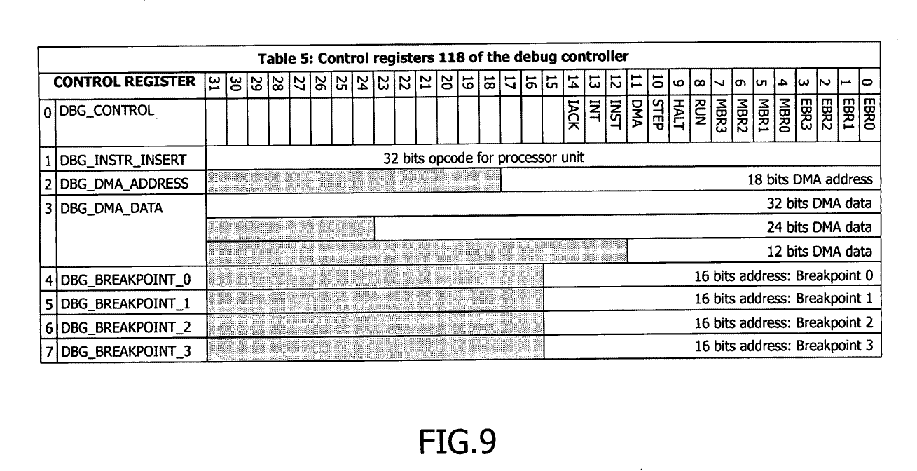

FIG. 9 shows in a fifth table the set of control registers of a debug controller,

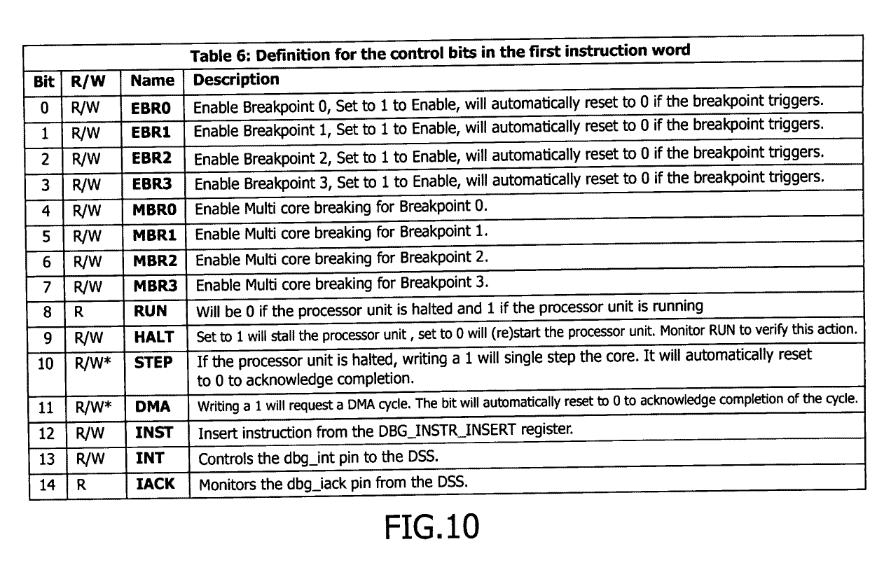

FIG. 10 shows in a sixth table the definition for control bits in the first instruction word in the fifth table.

FIG. 1 schematically shows a testable processor system 10, 20 comprising a plurality 10 of modules 11, 12, . . . , 1n. Each module comprises a processor unit 110 and a debug controller 111. The debug controllers 111, are coupled to a common TAP-controller, e.g. a JTAG TAP-controller 20.

FIGS. 2 and 3 show part of the system in more detail. The debug controllers 111, 121, 131, . . . 1n1, have a test data input Tin and a test data output Tout and at least one test register (FIG. 3: 112, 113). In the embodiment shown the debug controller has a test address register 112 and a test data register 113. The test data inputs and outputs of the debug controllers are arranged in a scanchain having an input for receiving test input data TDI from the TAP-controller and an output for providing test output data TDO to the TAP-controller. At least one debug controller 111 has a selection facility 115 to select whether data in the scanchain is either shifted through the at least one test register of that debug controller or is immediately forwarded from the test data input to the test data output of that debug controller. In the particular embodiment shown the debug controllers 111, 112, 113, . . . , 1n1, are identical, and each have such a selection facility. Hence only one of them will be described in detail here. In another embodiment the debug controllers may be different, for example to adapt them to their associated processor units.

As shown in FIG. 2 the first debug controller 111 has its test data input connected to test data output TDI of the TAP-controller. The next debug controller 121 has its test data input connected to the test data output of the first debug controller 121 and so on. The scanchain is completed with the last debug controller 1n1, which has its test data output coupled to test data input TDO of the TAP-controller. The debug controller 111 shown in more detail in FIG. 3. In this figure data paths which are part of the scan chain are indicated by thick lines. Thin lines indicate control signals. The debug controller 111 shown has a set of internal control registers 118 which can be controlled by a first test register 112 which functions as a register that addresses a particular control register from the set of control registers 118 (test address register), and by a second test register 114. The second test register 114 is a test data register which serves to capture data from the selected control register or to update the selected control register with data stored in said second test register. The debug controller 111 has a multiplexer 114 to select whether the first 112 or second test register 113 is coupled in the scanchain. The multiplexer 114 is controlled by a selection signal AD_SELECT from the TAP-controller 20. In the system according to the invention the debug controller 111 has a selection facility, in this case a multiplexer 115, which allows to bypass the test registers 113, 114, so that test data is immediately forwarded from the test data input Tin to the test data output Tout of that debug controller 111. In another embodiment the selection means may comprise a first and a second latch having an output enable/disable option instead of the multiplexer 115. The multiplexer 115 is controlled by a bypass register 117. If the bypass register 117 comprises a first logical value it causes the multiplexer 115 to select the output of the multiplexer 114. If it has a second logical value it causes the multiplexer 115 to select the test data input Tin of the debug controller 111. The debug controller 111 has a further multiplexer 116 that has a first input coupled to the bypass register 117 and a second input coupled to the output of the multiplexer 115. The further multiplexer 116 is controlled by the signal BYPASS_CNTRL of the TAP-controller 20. (FIG. 2)

In the embodiment shown, the TAP-controller 20 is a standard JTAG block, which contains an Instruction register, the ID code register and a TAP-controller bypass register. The TAP-controller is configured to have two external user data registers: The SYS_CONTROL register and the SYS_DEBUG register. The SYS_DEBUG register is a distributed register within all the serially connected debug controllers. The SYS_CONTROL register is a 3 bits register. Bit0 is the SYS_RESET bit. This signal can be connected to SOC reset controller 30 to reset all modules in the multiprocessor system. Bit 1 and 2 in the SYS_CONTROL register are the BYPASS_CNTRL and the AD_SELECT bit. The functionality of these bits will be explained in more detail in the sequel.

The instruction set of the TAP-controller is shown in Table 1 in FIG. 4. In addition to the standard JTAG instructions SAMPLE, PRELOAD, EXTEST CLAMP, and BYPASS instruction, it comprises the private instructions SYS_DEBUG and SYS_CONTROL.

The TAP-controller 20 communicates with the debug controllers 111, 121, 131 by means of the signals shown in Table 2 in FIG. 5.

The signal DBG_TDI is an output signal that provides test data to the scanchain.

The signal DBG_TDO is an input signal that provides test data from the scanchain to the TAP-controller.

The signal DBG_TCK is a serial data clock that indicates the pace at which the test data is provided to the scanchain.

The signal DBG_RESET synchronously resets all user registers.

The content of the scanchain is written into the corresponding registers as a result of the signal DBG_UPDATE.

The content of the registers is written into the scanchain by the signal DBG_CAPTURE.

The signal DBG_BYPASS_CONTROL, corresponding to the output signal BYPASS_CNTRL of the TAP-controller 20 puts all debug controllers in BYPASS_CONTROL mode, i.e. this has the result that data fed into the scanchain is guided through the debug controller bypass registers 117.

The signal AD_SELECT determines in a normal test mode, whether the test data should be guided via the test data register or the test address register.

The TAP-controller 20 can reset the debug controllers 111, 121 etc. with the signal SYS_RESET.

Communication signals between the debug controller 111 and the corresponding processor unit 110 are shown in Table 3 in FIG. 6.

The debug controller receives the clock signal dbg_clk_phi2 of the processor unit.

The debug controller can stall the processor unit with the signal dbg_stall_core and can check the stall status of the processor units with the signal dbg_stall_read.

The debug controller can monitor the program address bus dbg_pa.

The debug controller can control the instruction register of the processor unit with signals dbg_eir and dbg_eir-select.

The following signals enable the debug controller to perform DMA accesses to the processor unit. DMA data is respectively read and written via the DMA input bus dbg_dma_data_input and a DMA output bus dbg_dma_data_output, further using a DMA address bus dbg_dma_address. The following control signals are used for the DMA access dbg_dma_request to requests a DMA access, dbg_dma_rwn to indicate read or write mode and dbg_dma_acknowledge to verify whether the DMA request is handled.

The debug controller may interrupt the processor units with the signal dbg_int and verifies this by receiving a signal dbg_iack.

In addition, the debug controller has the possibility to generate a signal to stall the processor units connected to other debug controllers. The dbg_stall_others signal is used for this purpose. With the dbg_stall_remote input signal an other debug controller can stall the DSS connected to this debug controller. This is schematically shown in Table 4 in FIG. 7. These signals must be connected externally to the debug controller. For simple configurations the dbg_stall_remote signal is just a logical OR function of the dbg_stall_others of the other debug controllers as seen in FIG. 8. For more complicated multiprocessor systems, a more structured approach may be used to distribute the dbg_stall_others signals. E.g. a hierarchical approach, where for each group of modules the dbg_stall_other signals are combined by an OR-gate. The output signals of the OR-gates are combined into a next level OR-gate until a single dbg-stall-remote signal remains, which is used to stall each of the processor units, when activated. In again another embodiment the remote_stall_others is a pull down line, which can be pulled down by each of the debug controllers.

Table 5 in FIG. 9 shows in an embodiment, the available functions of the debug controller 11, mapped on the control registers 118. The first register DBG_CONTROL may be loaded with a set of control bits, which are described in more detail in the table in FIG. 10. The second register DBG_INSTR_INSERT is reserved for an opcode, here 32 bits, for the processor unit 110. The third and the fourth register are used to enable DMA access to the processor unit. The third register DBG_DMA_ADDRESS can be loaded with a DMA address, while the fourth register DBG_DMA_DATA serves to store DMA data, in this case 12 bits, 24 bits bits or 32 bits.

Up to four breakpoints may be specified by loading the desired address in one or more of the registers DBG_BREAKPOINT_{—}0 upto DBG_BREAKPOINT_{—}3.

Table 6 in FIG. 10 describes in more detail the function of the control bits in register 1 of the set of control registers 118. The breakpoints defined in registers four to seven are selectively activated by assigning a logical value 1 to the corresponding enable break control bits EBR0 to EBR3. As soon as a processor unit stops at this breakpoint the value of corresponding enable break control bits is reset to zero. In an other embodiment the processor has separate control bits BRS0 to BRS3 associated with the control bits EBR0 to EBR3. In that embodiment, the processor signals that it has stopped at the breakpoint by setting the associated control bit BRSi to a particular value, instead of resetting the bit EBRi to zero

Multicore breaking (i.e. stopping all processor units simultaneously) can be realized in an analogue way by setting one or more of the enable multicore break control bits MBR0 to MBR3. RUN is a read only bit which indicates whether the processor unit is running (1) or halted (0). As soon as the processor unit for which the multicore breakpoint set detects the corresponding address it stall itself and the other processor units.

By setting the control bit HALT to a logical value 0 or 1 the processor unit can be started or halted respectively. This action can be verified by monitoring the bit RUN.

From a halted state the processor units may proceed stepwise by setting the bit STEP in the control register. After the processor unit has performed the step it resets this bit.

A DMA cycle is initiated by setting the DMA bit to a logical 1. If the cycle is complete the DMA bit is automatically reset.

The bit INST is used to indicate that an instruction is to be inserted from the DBG_INSTR_INSERT register.

The interrupt signal from the debug controller to the processor units is controlled by the bit INT. The control bits IACK monitors the corresponding acknowledge signal from the processor units.

The operation of the testable processor system according to the invention will now be described with some examples.

### Select a Module

Consider the example, where the processor unit of module 2 out of four modules (n=4) is selected for debugging. This is achieved by the following steps:

Step 1: Set the BYPASS_CONTROL bit in the SYS_CONTROL register high. This has the effect that the BYPASS_CNTRL signal of the TAP-controller 20 assumes a logical value 1. As a result the bypass register 117 is switched in the scanchain in each of the debug controllers 111, 121, 131 . . . , 1n1. This implies that the signal BYPASS_CNTRL enables the bypass register 117 to accept the data from the test data input Tin, so that it can be loaded. It further causes the multiplexer 116 to select the output from this bypass register 117, so that the old content can be forwarded to the test data output Tout.

Step 2: Shift “1011” (LSB first) into the SYS_DEBUG register. After this step the bypass registers of the 4 debug controllers respectively contain the values 1,0,1 and 1. Step 3: Set the BYPASS_CONTROL bit low.

This has the effect that the first 111, the third 131 and the fourth module 1n1 are in bypass mode. For example data arriving at test data input Tin of debug controller 111 is guided via multiplexer 115 and multiplexer 116 to the test data output Tout. In the second debug controller 121 however, the value 0 in the bypass register 117, causes the multiplexer 115 to select the data from multiplexer 114. This multiplexer 114 retrieves it data either from test address register 112 or test data register 113 dependent on the AD_SELECT signal. This signal also determines whether the new test data at test data input Tin is read in the test address register 112 or the test data register 113.

Now the SYS_DEBUG register contains only the test address register 112 or the test data register 113 of the second module 121. This allows to perform debugging tasks on this module 121 without needing additional shift cycles to shift the data through the registers of the other debug controllers.

All other use cases can be accomplished by accessing the debug control registers 118 of the selected debug controller. These registers are accessible via the test address register 112 and the test data register 113. A selection between the test address register 112 and the test data register 113 is made by the signal AD_SELECT from the TAP-controller. The signal AD_SELECT on its turn is controlled by bit 2 in the SYS_CONTROL register. To access a particular control register, the register address to be accessed is written in the test address register 112. Subsequently data can be written to the test data register 113. In an update cycle this data is copied from the test data register 113 to the addressed control register of the set 118. In a capture cycle data is copied from the addressed control register to the test data register 113. In the embodiment shown only 3 of the address bits are needed to address the 8 control registers, up to 8 control registers can be added in future enhancements if needed.

### Polling the DBG_CONTROL Register

The STEP and DMA bits in the first register of the set 118 have a special control function. The functions corresponding with those bits are activated by writing a ‘1’ to the bit and completion is acknowledged by this function by making the bit ‘0’. The application has to poll the bit to make sure the function has been completed. Due to the nature of JTAG Data Register accesses, a read (Capture-DR state) [IEEE 1149.1] has to be followed by an ‘Update-DR state’ which will copy the current shift register to the data register. So, the original date needs to be shifted in after a ‘Capture-DR’ to prevent the original date to be lost. If this is done for the special bits mentioned above, the related function could be activated again. This can be prevented by always shifting in a ‘0’ for such a bit after doing a read on the register. Note that this writing of a ‘0’ will not influence the state of the function, and the acknowledge status.

### Issue a DMA Request

Step 1: Load the DBG_DMA_ADDRESS register, i.e. control register 2 in set 118.

Step 2: In case of a write also load the DBG_DMA_DATA register (#3 in set 118).

Step 3: Set the DMA bit to one, to indicate the request for the DMA cycle. Preferably it is verified before this step whether the DMA bit is low. If this is not the case, an execution handler may be activated.

Step 4: Poll the DBG_CONTROL register until the DMA bit is low to verify completion.

A too long duration of the step 4, may be indicative of an error. Preferably execution handling is performed in this case.

Step 5: In case of a read, read back the data from the DBG_DMA_DATA register.

In a preferred embodiments the DBG_DMA_ADDRESS register will increment by 1.

if DMA cycle is done. This facilitates reading a writing to a contiguous block of memory addresses

### Halt

Step 1: Set the HALT bit in the DBG_CONTROL register.

Step 2: Poll until the RUN bit in the DBG_CONTROL register is low.

### Single Step

Step 1: Single step mode can be activated after the processor unit is halted (See Halt).

Step 2: Set STEP bit to initiate a step

Step 3: Poll for the STEP bit to go low. At that moment the single step is performed.

### Insert Instruction

An additional instruction may be inserted in the instruction stream of the processor unit by following sequence.

Step 1: Make sure the processor unit is halted (See halt).

Step 2: Load the EPD_INSTR_INSERT register with a valid instruction for the processor unit

Step 4: Set the INST bit in the DBG_CONTROL register high.

Step 3: Perform one step (See step 2 and step 3 of the procedure Single Step. Step 1 of the procedure may be skipped as the processor unit was already halted)

### Setting Hardware Break Points

Step 1: load one of the breakpoint registers (DBG_BREAKPOINT_{—}[0-3])

### Stop Execution at Breakpoint

Step 1 When one or more of the breakpoint registers have been loaded as described above, one or more EBR (enable breakpoint) bits in the DBG_CONTROL register can be selected by setting the corresponding EBR bit(s) high.

Step 5: Poll until the (one of the) EBR bit(s) goes low. If this occurs the processor unit has stopped at the corresponding breakpoint.

### Stop Execution of all Modules at Breakpoint

Analogously it is possible to stop execution of all modules at a breakpoint. However a breakpoint for all modules should be indicated by setting a MBR (Multicore Breakpoint) bit in the DBG_CONTROL register high. In this case, if a processor unit for which the MBR is set high encounters an address marked as breakpoint, it does not only stall itself but also stalls the others via the remote stall interface.

### Interrupt the Processor Unit

When the processor unit is halted it may be forced to carry out its interrupt handler as follows. First the INT bit in the DBG_CONTROL register is set high. Then the processor unit is single stepped until the IACK bit in the DBG_CONTROL register goes high. In this way the processor signals that it has started the interrupt routine

It is remarked that the scope of protection of the invention is not restricted to the embodiments described herein. Parts of the system may implemented in hardware, software or a combination thereof. Neither is the scope of protection of the invention restricted by the reference numerals in the claims. The word ‘comprising’ does not exclude other parts than those mentioned in a claim. The word ‘a(n)’ preceding an element does not exclude a plurality of those elements. Means forming part of the invention may both be implemented in the form of dedicated hardware or in the form of a programmed general purpose processor. The invention resides in each new feature or combination of features.

1. A testable processor system comprising a plurality of modules, each module comprising a processor unit and a debug controller, the debug controllers being coupled to a common test access point controller, wherein the debug controllers have a test data input and a test data output and at least one test register, wherein the test data inputs and outputs of the debug controllers are arranged in a scan chain having an input for receiving test input data from the TAP-controller and an output for providing test output data to the TAP-controller, wherein at least one debug controller has a selection facility to select whether data in the scan chain is either shifted through the at least one test register of that debug controller or is immediately forwarded from the test data input to the test data output of that debug controller, wherein the at least one debug controller has a bypass register which controls the selection facility and wherein the TAP-controller provides a control signal which, when active, selects the bypass register as part of the scan chain.

2. A testable processor system according to claim 1, wherein the control signal when active, deselects all other test registers of the debug controllers in the scan chain.

3. A testable processor system according to claim 1, wherein the at least one debug controller has an output for providing a signal capable of causing each of the other debug controllers to halt their processor unit.

4. Method for testing a processor system having a plurality of modules, each module comprising a processor unit and a debug controller, the debug controllers being coupled to a common test access point controller, wherein the debug controllers have a test data input, a test data output and at least one test register, wherein the test data inputs and outputs of the debug controllers are arranged in a scan chain having an input for receiving test input data from the TAP-controller and an output for providing test output data to the TAP-controller, which method comprises the following steps: selecting the bypass registers as part of the scan chain in the debug controllers, loading the bypass registers via the scan chain with control data, shifting data through the scan chain, wherein the control data in the bypass register of at least one of the debug controllers causes data in the scanchain to be immediately forwarded from the test data input to the test data output of that debug controller.
